(19) United States
(12) Patent Application Publication
(10) Pub. No.: US 2025/0196565 A1
(43) Pub. Date: Jun. 19, 2025

(54) SENSOR MODULE HAVING AN ENVIRONMENT SENSOR AND A COOLING DEVICE

(71) Applicant: Webasto SE, Stockdorf (DE)

(72) Inventor: Magnus SVIBERG, Stockdorf (DE)

(21) Appl. No.: 18/965,305

(22) Filed: Dec. 2, 2024

(30) Foreign Application Priority Data
Dec. 14, 2023 (DE) 10 2023 135 172.9

(51) Int. Cl. B60H 1/00; B60H 1/22; B60R 11/00; B60R 11/02

(52) U.S. Cl. CPC B60H 1/00271; B60H 1/22; B60R 11/00; B60R 11/0258; B60H 2001/2271; B60R 2011/004

(57) ABSTRACT

A sensor module having a sensor viewing area, an environment sensor, which is configured for charting a vehicle environment through the sensor viewing area, and a cooling element having a cooling component, the cooling component being configured to dissipate waste heat generated by the environment sensor and/or environment heat supplied to the sensor module from the exterior of the sensor module from the sensor module and/or from the environment sensor, the environment sensor being disposed on the sensor module so as to be movable between a retracted position and an extracted position, wherein the cooling component has a first component part and a second component part, the first component part being movable in such a manner with respect to the second component part that the cooling component provides a smaller cooling surface and/or a smaller cooling volume in the retracted position than in the extracted position.

### CROSS-REFERENCE TO RELATED APPLICATION

This application claims the benefit of German patent application No. 10 2023 135 172.9, filed Dec. 14, 2023, which is incorporated herein by reference in its entirety.

### TECHNICAL FIELD

The invention relates to a sensor module, in particular a roof sensor module (RSM) for a passenger car, the sensor module having a sensor viewing area, an environment sensor which is configured for charting a vehicle environment through the sensor viewing area, and a cooling device having a cooling component. The cooling component is configured to dissipate waste heat generated by the environment sensor and/or environment heat supplied to the sensor module from the outside from the sensor module and/or environment sensor. The environment sensor is movably disposed on the sensor module between a retracted position and an extracted position. The invention also relates to a roof sensor module having such a sensor module. The invention also relates to a motor vehicle having such a sensor module and/or such a roof sensor module.

### BACKGROUND

Vehicle roofs are well known in practice. A vehicle roof can, for example, be designed as a roof sensor module which can be mounted as a separate unit on a vehicle chassis of a passenger car which forms a vehicle body shell. As an interface to the vehicle roof, the vehicle chassis comprises roof beams, which can be designed as longitudinal beams and/or transverse beams and represent a support device on the vehicle body. The vehicle roof comprises a roof skin, which forms an outer viewing surface and has sensor viewing areas through which environment sensors, which are used to chart a vehicle environment and are disposed under the roof skin, can chart the vehicle environment.

Autonomous or semi-autonomous vehicles include, for example, a roof designed as a roof sensor module (RSM), which is equipped with a large number of environment sensors. To ensure uninterrupted availability of the environment sensors, they must be kept within a certain temperature window, for which a cooling device is used.

DE 10 2019 122 193 B4, for example, discloses a movable environment sensor and a cooling device for thermal management of the environment sensor and/or other components.

With a movable environment sensor, the cooling device often requires much installation space, especially in a vehicle height direction, which is disadvantageous for the vehicle layout and/or vehicle design.

### SUMMARY

One object of the invention is to provide an improved sensor module.

In the case at hand, the object is attained by a sensor module having the features of claim 1. In the case at hand, the object is attained by a roof sensor module having the features of claim 10. In the case at hand, the object is attained by a motor vehicle having the features of claim 11.

Advantageous embodiments of the invention are the subject matter of the dependent claims. Moreover, any and all combinations of at least two features disclosed in the description, the claims, and/or the figures fall within the scope of the invention. In particular, linguistically common rephrasing and/or an analogous replacement of respective terms within the scope of common linguistic practice, in particular the use of synonyms backed by the generally recognized linguistic literature, are of course comprised by the content of the disclosure at hand without every variation having to be expressly mentioned.

Presently, a sensor module is proposed, in particular for a passenger car. The sensor module has a sensor viewing area, an environment sensor, which is configured for charting a vehicle environment through the sensor viewing area, and a cooling element having a cooling component. The cooling component is configured to dissipate waste heat generated by the environment sensor and/or environment heat supplied to the sensor module from the exterior of the sensor module from the sensor module and/or from the environment sensor. The environment sensor is disposed on the sensor module so as to be movable between a retracted position and an extracted position. The cooling component has a first component part and a second component part. The first component part is movable in such a manner with respect to the second component part that the cooling component provides a smaller cooling surface and/or a smaller cooling volume in the retracted position than in the extracted position.

The cooling component is therefore preferably divided into two or more parts, namely the component parts. The component parts preferably partially or fully engage with each other when the environment sensor is in the retracted position. Alternatively or in addition, the component parts at least partially surround each other. In this manner, a smaller surface area and/or a smaller volume can be provided when the environment sensor and/or another component of the sensor module is lowered or retracted. In this manner, a larger cooling surface and/or a larger cooling volume can also be provided when the environment sensor and/or another component of the sensor module is raised or extracted.

The advantage of this version of the sensor module is that it enables improved styling and/or design of the overall vehicle due to the reduction in installation space. Equally, the arrangement of vehicle components, particularly in the roof area, can also be improved. Overall, the use of installation space is optimized. The present sensor module also provides more freedom in the selection and/or positioning of the sensor module in relation to a vehicle component, for example a vehicle roof and/or a vehicle chassis. Likewise, the cooling device enables effective cooling and/or air conditioning of the sensor module in both positions, i.e., in the retracted position and in the extracted position and/or in a plurality of possible intermediate positions. The present sensor module is also less complex. Weight and costs can also be saved.

The sensor viewing area can be formed in a cover and/or a casing part of the sensor module. The sensor viewing area can be provided as a window in an opening of such a cover and/or such a casing part. The sensor viewing area can also be formed integrally and/or in one piece with such a cover and/or such a casing part. In particular, the sensor viewing area is transparent for a wavelength range between 300 nm and 2000 nm. It is also advantageous if the sensor viewing area is transparent to radar beams.

The environment sensor of the vehicle roof can be designed in a variety of manners, use electromagnetic radiation and/or acoustic waves and have, for example, a lidar sensor, a radar sensor, an optical sensor such as a camera, an ultrasonic sensor, an antenna device and/or the like. If the environment sensor is a lidar sensor, it preferably operates in a wavelength range of around 905 nm or even around 1550 nm. A camera used as an environment sensor can operate in the wavelength range of visible light and/or in the infrared range.

The cooling device having the cooling component can also be configured to control temperature of the environment sensor and/or other components of the sensor module to be controlled in temperature. The cooling device can thus be understood as a temperature control device which can be used both for cooling and/or for heating the environment sensor and/or the other components of the sensor module to be controlled in temperature. The cooling device is preferably configured to keep the environment sensor and/or other components of the sensor module to be controlled in temperature at a predetermined target temperature or within a predetermined target temperature interval, in particular to enable optimum operation.

The environment sensor is movably disposed on the sensor module at least between the retracted position and the extracted position. The environment sensor can preferably be moved into a number of intermediate positions between the retracted position and the extracted position.

The cooling component has a first component part and a second component part. It is understood that the cooling component can also have more than two component parts.

In a preferred embodiment, the first component part is movable in such a manner with respect to the second component part that, when in the retracted position, the first component part engages at least partially in the second component part or at least partially surrounds the second component part in order to thus provide the smaller cooling surface and/or the smaller cooling volume than in the extracted position.

The first component part is movable with respect to the second component part. This means that the first part can move or change its position in relation to the second part. The design of the sensor module has two main positions-a retracted and an extracted position. These positions preferably also refer to the relative position of the two component parts to each other. In the retracted position, the first component part engages at least partially with the second component part. This preferably means that a part of the first component part moves into the area of the second component part or overlaps with it or is located within this area. Alternatively or additionally, the first component part can at least partially surround the second component part. This implies that the first component part partially encloses or surrounds the second component part. The aim of this movement or arrangement is to provide a smaller cooling surface and/or a smaller cooling volume in the retracted position than in the extracted position. In this manner, the size of the cooling surface and/or the cooling volume can be varied depending on the position of the sensor module and/or the environment sensor. The cooling device can therefore preferably change its shape or configuration in order to achieve different cooling capacities and/or efficiencies and/or different installation space requirements.

In a preferred embodiment, the first component part is formed to be complementary to the second component part.

The first component part is formed to be complementary to the second component part. This preferably means that the shape, size, and/or functionality of the first component part is/are designed to match or fit with the features of the second component part. The component parts could be designed to physically fit together, for example by interlocking shapes. The functionalities of the two component parts could be coordinated in such a manner that together they form an overall system whose performance is optimized by the interaction of the two component parts. The component parts could also be coordinated in their external appearance or design in order to achieve a uniform or harmonious overall appearance.

In a preferred embodiment, the first component part is disposed directly or indirectly on the environment sensor and is thus extractable and retractable with the environment sensor, the second component part being disposed on an immovable casing or on an immovable support component of the sensor module.

The first component part is mounted to the environment sensor either directly or via an intermediate element (indirectly). This means that the first component part is either physically directly adjacent to the environment sensor or connected to it by another part or mechanism. The first component part is designed so that it can be retracted and extracted together with the environment sensor. This implies a movable construction in which the first component part and the environment sensor can be retracted and extracted in an essentially synchronized motion or at least in a motion-coupled motion. The second component part is preferably disposed on an immovable casing or on an immovable support component of the sensor module. This means that the second component part can be permanently mounted and does not move together with the first component part or the environment sensor. The first component part preferably takes on a functional role which is directly or indirectly related to the movement or positioning of the environment sensor. The second component part preferably serves as a stable base or anchor point for the cooling device, with its immobility providing a constant reference position or structural integrity.

In a preferred embodiment, the first component part is extractable and retractable with respect to the second component part. By retracting and extracting the environment sensor, the first component part can also be retracted and extracted with respect to the second component part. In this manner, the cooling surface and/or the cooling volume can be reduced or increased depending on the direction of movement. In the retracted position, the cooling component preferably has a minimal cooling surface and/or a minimal cooling volume. In the extracted position, the cooling component preferably has a maximum cooling surface and/or a maximum cooling volume.

In a preferred embodiment, the cooling component has a heat exchanger.

A heat exchanger is preferably a device which transfers heat from one medium (such as a liquid, air or steam) to another without the media coming into direct contact with each other. The components of a heat exchanger can vary depending on the type of heat exchanger. The heat exchanger can have tubes and/or plates through which the heat transfer medium flows. The heat exchanger may have a casing which comprises the tubes or plates and is configured to allow the secondary medium from or to which heat is transferred to come into contact with the exterior of the tubes or plates. The heat exchanger may have fins or ribs to increase the cooling surface area and thus increase the heat transfer efficiency. The heat exchanger may have a circulation pump and/or a fan to move the media through the heat exchanger. The aforementioned components of the heat exchanger may represent the first and/or second component part in any configuration.

In a preferred embodiment, the cooling component has a cooling body. The first component part and the second component part each have a plurality of cooling fins. The cooling fins of the first component part interlacing with the cooling fins of the second component part in such a manner, in particular like a comb, when in the retracted position that the cooling volume of the cooling body is reduced with respect to the extracted position.

The cooling component has a cooling body. Cooling bodies are usually made of a thermally conductive material such as aluminum or copper and are used to absorb heat from a device or a component and dissipate it to the environment. Both the first component part and the second component part each have a plurality of cooling fins. Cooling fins are preferably thin, plate-like or fin-like extensions which increase the surface area of the cooling body in order to improve heat dissipation to the ambient air. The arrangement of the cooling fins on both component parts improves heat dissipation via an increased surface area. In the retracted position, the cooling fins of the first component part interlace with the cooling fins of the second component part at least in certain areas and in particular in a comb-like manner. This means that the fins are designed in such a manner that they can interlock, similar to the teeth of two interlocking combs. This design allows for a compact arrangement of the component parts when retracted and may provide improved heat dissipation due to the closer contact between the fins. In the retracted position, the cooling volume of the cooling body is reduced compared to the extracted position. This means that the cooling body takes on a more compact shape in the retracted position.

In a preferred embodiment, the cooling fins are shaped in such a way that they touch each other in an extracted position. This improves heat dissipation through contact. The cooling fins preferably have a trapezoidal design or a trapezoidal shape for this purpose. Alternatively, the cooling fins can have an inflated design or shape. It is particularly preferred that the cross-section of the cooling fins are designed to incline from a free top end of the corresponding cooling fin to a bottom end.

In a preferred embodiment, the cooling component has a cooling channel. The first component part has a cooling channel base and the second component part has a cooling channel lid.

The cooling component comprises a cooling channel, which is preferably an integral part of the cooling device. A cooling channel is preferably used to guide a cooling medium (such as air or a liquid) through the component in order to transport or dissipate heat away from the environment sensor and/or a heat source. The first component part preferably has a cooling channel base. This is preferably the part of the cooling channel which forms the main path or the bed for the cooling medium. The base is preferably designed so that it efficiently guides the cooling medium through the channel and enables optimum heat absorption from the surrounding components. The second component part preferably comprises a cooling channel cover. This cover closes off the cooling channel, preferably to keep the cooling medium within the intended path and to prevent leakage or spillage of the medium. The cover can preferably contribute to controlling the flow and/or volume flow of the cooling medium within the channel and/or to improving the heat transfer efficiency.

A roof sensor module for forming a vehicle roof is also claimed in the present case. The roof sensor module can be disposed as a preassembly unit on a vehicle chassis. The roof module has a panel component, which acts as a roof skin at least in areas, and a roof module of this type. The sensor module is disposed on the panel component. The roof sensor module preferably forms a structural unit in an integrated manner, which accommodates components configured for autonomous or semi-autonomous driving of the vehicle in question. The roof sensor module, in which a plurality of functional elements can preferably be integrated, is a compact structural unit which can be pre-assembled so that it only needs to be connected to a vehicle chassis and/or vehicle body shell by the vehicle manufacturer. The roof sensor module is preferably connected to roof beams, such as roof side beams and/or longitudinal roof beams. The roof sensor module is a roof sensor module (RSM), which enables autonomous or semi-autonomous driving of the vehicle in question. A motor vehicle which is equipped with such a roof sensor module and is designed as an autonomous driving vehicle preferably drives independently in an autonomous driving mode, i.e., at least without significant intervention by a driver. In a semi-autonomous driving mode, the roof sensor module according to the invention forms part of a driver assistance system, for example. The roof sensor module can be designed with a transparent fixed roof section and/or a roof opening system and a roof opening. In particular, the roof sensor module at least partially forms a roof of a passenger car. However, it can also be a roof of a commercial vehicle, for example a delivery van, a bus, an autonomous minibus, such as a so-called people mover, or a truck tractor.

A motor vehicle is also claimed which has at least one such sensor module and/or at least one such roof sensor module. The roof sensor module can be disposed as a pre-assembly unit on a vehicle chassis of the motor vehicle. In other words, in particular a vehicle chassis of the motor vehicle can be connected to a prefabricated and/or preassembled roof sensor module, which is designed as a sensor roof module and/or roof sensor module.

Further advantages and advantageous embodiments of the subject matter of the invention can be seen in the description, the drawing and the claims.

### BRIEF DESCRIPTION OF DRAWINGS

Exemplary embodiments of a motor vehicle having a vehicle roof according to the invention are shown schematically in simplified form in the drawing and are explained in more detail in the following description.

FIG. 1 shows a schematic view of a motor vehicle having a vehicle roof and an exemplary embodiment of a sensor module.

FIG. 2 shows a schematic view of a sensor module according to a first embodiment in an extracted position.

FIG. 3 shows a schematic view of a sensor module according to the first embodiment in a retracted position.

FIG. 4 shows a schematic view of a sensor module according to a second embodiment in an extracted position.

FIG. 5 shows a schematic view of a sensor module according to the second embodiment in a retracted position.

FIG. 6 shows a schematic view of a sensor module according to a third embodiment in an extracted position.

FIG. 7 shows a schematic view of a sensor module according to the third embodiment in an extracted position.

FIG. 8 shows a schematic view of a sensor module according to a fourth embodiment in an extracted position.

FIG. 9 shows a schematic view of a sensor module according to the fourth embodiment in an extracted position.

### DETAILED DESCRIPTION

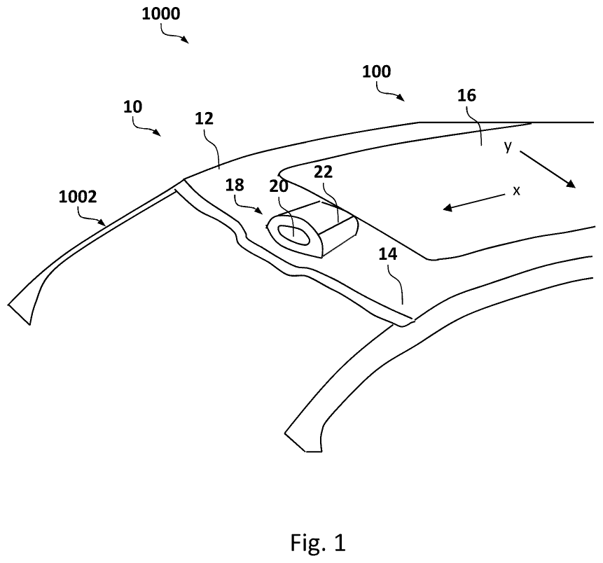

FIG. 1 schematically shows a motor vehicle 1000, which has a vehicle chassis 1002. Furthermore, the motor vehicle 1000 has a roof sensor module 10, which is disposed as a pre-assembly unit on the vehicle chassis 1002 and forms at least areas of a vehicle roof 100 of the motor vehicle 1000. The roof sensor module 10 extends along a longitudinal vehicle direction x and a vehicle width direction y.

In alternative embodiments, the vehicle roof 100 can also be a vehicle roof which is not designed as a roof sensor module. Thus, all embodiments also refer to such a vehicle roof 100.

The roof sensor module 10 comprises a panel component 12, which forms at least areas of a roof skin 14 of the vehicle roof 100. According to FIG. 1, the roof sensor module 10 comprises a fixed roof element 16, which forms an at least partially transparent viewing area of the vehicle roof 100. In other or supplementary embodiments, the roof sensor module 10 can have a roof opening system comprising a lid element which can be displaced to selectively open or close a roof opening.

The roof sensor module 10 (see FIG. 1) and/or the vehicle roof 100 has a sensor module 18. The sensor module 18 has a sensor viewing area 20. Furthermore, the sensor module 18 has at least one environment sensor 22, which is configured for charting a vehicle environment through the sensor viewing area 20.

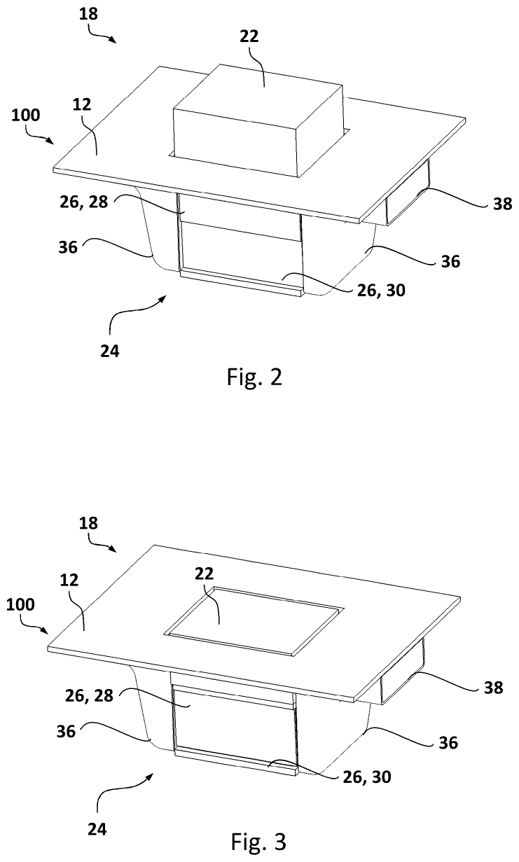

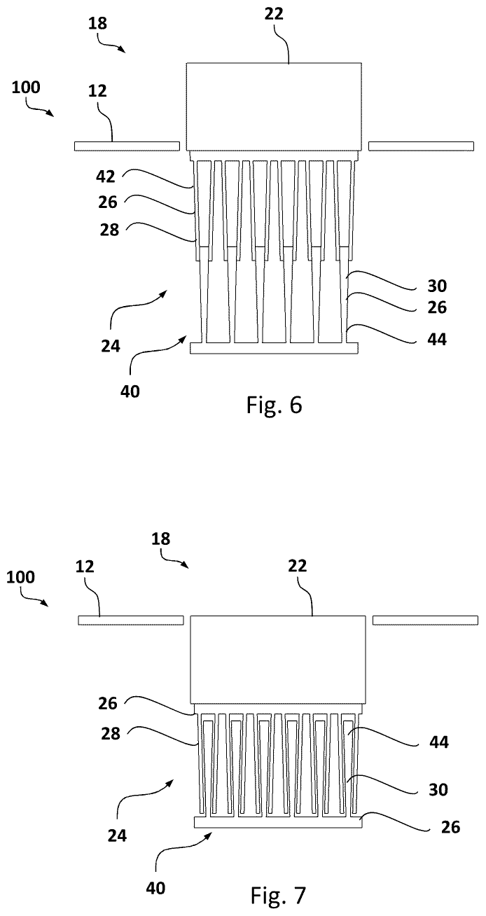

With reference to FIGS. 2 to 9, the sensor module 18 also has a cooling device 24 having at least one cooling component 26. The cooling component 26 is configured to dissipate waste heat generated by the environment sensor 22 and/or environment heat supplied from the exterior to the sensor module 18 from the sensor module 18 and/or environment sensor 22.

The environment sensor 22 is movably disposed on the sensor module 18 between a retracted position (see FIGS. 3, 5, 7, 9) and an extracted position (see FIGS. 2, 4, 6, 8).

The cooling component 26 has a first component part 28 and a second component part 30. The first component part 28 is movable in such a manner with respect to the second component part 30 that the cooling component 26 provides a smaller cooling surface and/or a smaller cooling volume in the retracted position than in the extracted position. The first component part 28 is movable in such a manner with respect to the second component part 30 that, when in the retracted position, the first component part 28 interlaces at least partially with the second component part 30 (see FIGS. 5 and 7) or at least partially surrounds the second component part 30 (see FIGS. 3 and 9) in order to provide the smaller cooling surface and/or the smaller cooling volume than in the extracted position. The first component part 28 is therefore formed to be complementary to the second component part 30.

As can be seen from FIGS. 2 to 9, the first component part 28 is disposed directly on the environment sensor 22 and thus is retractable and extractable with the environment sensor 22. The second component part 30, on the other hand, is disposed on an immovable casing or on an immovable support component 32 of the sensor module 18. The first component part 28 is thus retractable and extractable with respect to the second component part 30.

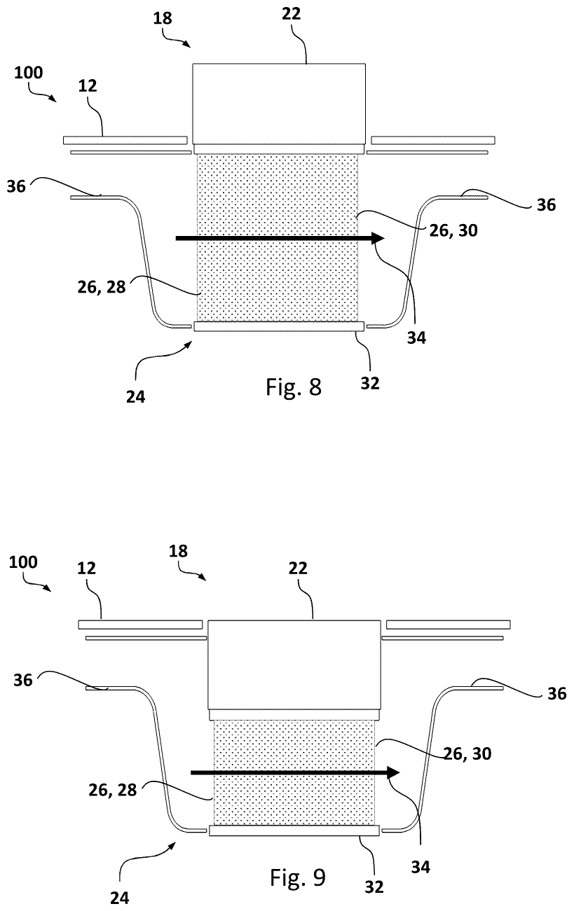

According to FIGS. 2 and 3 and FIGS. 8 and 9, the cooling component 24 has a heat exchanger. FIGS. 8 and 9 also show a possible air flow direction 34 through the heat exchanger by means of an arrow.

According to FIGS. 2 and 3 and FIGS. 8 and 9, a cooling channel 36 is also shown, through which cooling air and/or a cooling medium can be conducted. In other embodiments, the cooling component 24 may have a cooling channel or a channel section, the first component part 28 being able to form a cooling channel base and the second component part 30 being able to form a cooling channel cover. In FIGS. 2 and 3, an air inlet and/or air outlet (depending on the direction in which the cooling medium flows) is shown as an exemplary embodiment with the reference sign 38.

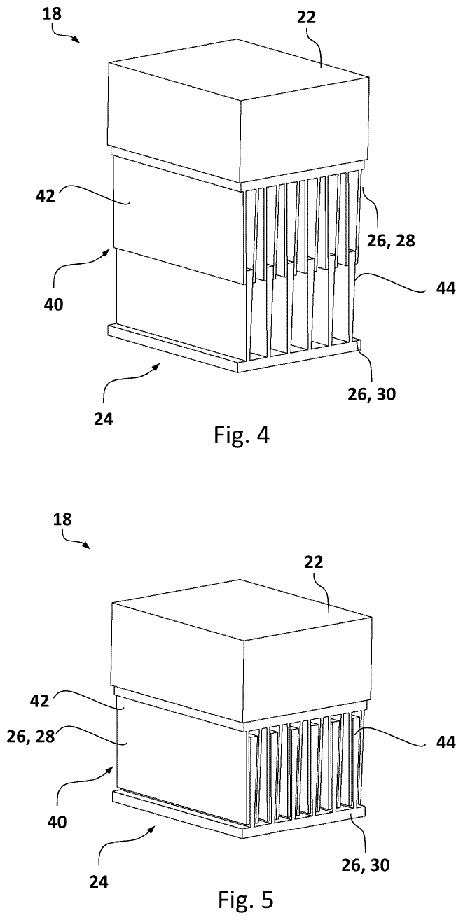

According to FIGS. 4 to 7, the cooling component 24 can have a cooling body 40. The first component part 28 has a plurality of cooling fins 42. The second component part 30 has a plurality of cooling fins 44. The cooling fins 42 of the first component part 28 interlace with the cooling fins 44 of the second component part 30 in such a manner when in the retracted position that the cooling volume of the cooling body 40 is reduced relative to the extracted position. The cooling fins 42 are shaped in such a manner in this case that they touch each other in the extracted position. This improves heat dissipation through contact. The cooling fins 42 have a trapezoidal shape for this purpose. Alternatively, the cooling fins 42 can have an inflated design. It can be seen that the cross-section of the cooling fins 42 rises from a free top end of the corresponding cooling fin 42 to a bottom end of the corresponding cooling fin 42.

### REFERENCE NUMERALS

10 roof sensor module
12 panel component
14 roof skin
16 fixed roof element
18 sensor module
20 sensor viewing area
22 environment sensor
24 cooling device
26 cooling component
28 component part
30 component part
32 casing or support component
34 air flow direction
36 cooling channel
38 air inlet or air outlet
40 cooling body
42 cooling fins
44 cooling fins
100 vehicle roof
1000 motor vehicle
1002 vehicle chassis
x longitudinal vehicle direction
y vehicle width direction

1. A sensor module comprising:
a sensor viewing area,
an environment sensor, which is configured for charting a vehicle environment through the sensor viewing area, and
a cooling element having a cooling component,
the cooling component being configured to dissipate waste heat generated by the environment sensor and/or environment heat supplied to the sensor module from the exterior of the sensor module from the sensor module and/or from the environment sensor,
the environment sensor being disposed on the sensor module so as to be movable between a retracted position and an extracted position,
wherein the cooling component has a first component part and a second component part, the first component part being movable in such a manner with respect to the second component part that the cooling component provides a smaller cooling surface and/or a smaller cooling volume in the retracted position than in the extracted position.

2. The senor module according to claim 1, wherein the first component part is movable in such a manner with respect to the second component part that, when in the retracted position, the first component part engages at least partially in the second component part or at least partially surrounds the second component part in order to thus provide the smaller cooling surface and/or the smaller cooling volume than in the extracted position.

3. The sensor module according to claim 1, wherein the first component part is formed to be complementary to the second component part.

4. The sensor module according to claim 1, wherein the first component part is disposed directly or indirectly on the environment sensor and is thus extractable and retractable with the environment sensor, the second component part being disposed on an immovable casing or on an immovable support component of the sensor module.

5. The sensor module according to claim 1, wherein the first component part is extractable and retractable with respect to the second component part.

6. The sensor module according to claim 1, wherein the cooling component has a heat exchanger.

7. The sensor module according to claim 1, wherein the cooling component has a cooling body,
the first component part and the second component part each have a plurality of cooling fins,
the cooling fins of the first component part interlacing with the cooling fins of the second component part in such a manner when in the retracted position that the cooling volume of the cooling body is reduced with respect to the extracted position.

8. The sensor module according to claim 7, wherein the cooling fins are formed in such a manner that they touch when in the extracted position, the cooling fins preferably being trapezoidal or inflated, and a corresponding cross section of the cooling fins preferably being designed to incline from a corresponding free top end to a corresponding free bottom end.

9. The sensor module according to claim 1, wherein the cooling component has a cooling channel, the first component part having a cooling channel base and the second component part having a cooling channel lid.

10. A roof sensor module for forming a vehicle roof, which is disposed on a vehicle chassis as a pre-assembly construction unit, the roof sensor module having a panel component acting as a roof skin at least in areas and a sensor module according to claim 1, the sensor module being disposed on the panel component.

11. A motor vehicle comprising:
a vehicle chassis,
a sensor module according to claim 1, and/or
a roof sensor module for forming a vehicle roof, the roof sensor module having a panel component acting as a roof skin at least in areas and the sensor module being disposed on the panel component,
the sensor module and/or the roof sensor module being disposed on the vehicle chassis as a pre-assembly construction unit.
